(19) United States
(12) Patent Application Publication
(10) Pub. No.: US 2008/0299780 A1
(43) Pub. Date: Dec. 4, 2008

(54) Method and apparatus for laser oxidation and reduction

(75) Inventors: David J. Elliott, Wayland, MA (US); Victoria M. Chaplick, Webster, MA (US)

Correspondence Address: WOLF GREENFIELD & SACKS, P.C., 600 ATLANTIC AVENUE, BOSTON, MA, 02210-2206, US

(73) Assignee: UV Tech Systems, Inc., Sudbury, MA (US)

(21) Appl. No.: 11/809,749

(22) Filed: Jun. 1, 2007

(51) Int. Cl. H01L 21/31

(52) U.S. Cl. 438/770; 257/E21.24

(57) ABSTRACT

A method and apparatus using electromagnetic radiation and gas to create oxidation and reduction reactions on a device, such as a semiconductor wafer surface. In one embodiment, a scanned laser and gas may be employed in a number of oxidation and/or reduction reactions in a single system without using multiple pieces of equipment, corrosive chemicals and gases, high temperature and pressure chamber environments, waste treatment processes, and/or extra process steps typically required in existing processes.

### FIELD OF THE INVENTION

The present invention relates generally to a method and apparatus for the treatment of surfaces, such as a semiconductor wafer surface, with electromagnetic radiation and gas.

### BACKGROUND OF THE INVENTION

Oxidation and reduction processes are used, e.g., in semiconductor processing, to both grow films in an additive process, and remove films in a subtractive process. Oxidation reactions are used for at least two primary kinds of processes: cleaning or oxidative combustion of organic films, which is a subtractive process, and oxidative film forming, which is an additive process. Reduction reactions are typically subtractive, and can be used to remove both organic and inorganic films from surfaces. In practice, these processes in the related art have many of the same characteristics and limitations. For example, both oxidation and reduction reaction processes require multiple, separate pieces of complex, expensive equipment that take up considerable factory floor space. As currently employed, both oxidation and reduction processes also involve the use of environmentally harmful materials, and require that the wafer be subjected to relatively high thermal environments that can cause undesirable movement of surface dopants and physical distortion of the wafer itself.

Oxidation reactions are used on two primary types of surfaces: inorganic films such as copper, aluminum, silicon nitride, silicides, silicon and other semiconductor films, and on organic films such as photoresist. Many types of films are used in integrated circuit manufacturing, including metals such as copper, aluminum, alloys of conductive metals including aluminum, and a range of insulating or semi-conducting films such as doped silicon, silicon nitride, oxy-nitrides, silicides, and ordinary silicon dioxide.

Regarding oxidation processes used in cleaning applications, oxidation reactions using oxygen and ozone are used to remove films and residues of organic material, which are combusted in the oxidation reaction. In oxidative film forming processes, oxygen and ozone gases are used to grow, for example, layers of some kind of oxide. If the substrate is silicon, the resulting film from oxidation will be silicon dioxide. If the film is copper, the resulting film will be copper oxide. Other films, such as silicides, can also be grown on semiconductor surfaces using combinations of gases and an energy driver, such as heat. Therefore, oxidation reactions encompass both subtractive removal of material by oxidative combustion of hydrocarbons, and additive growth of material by oxidation of the substrate. These kinds of reactions typically occur in a pressurized or vacuum chamber where the substrate being treated is inserted and subjected to the oxidizing environment in the presence of selected gases. The typical energy driver used in these oxidation reactions is heat, mainly for the purpose of increasing the rate of the reaction.

First, we discuss oxidation processes for cleaning, which typically involve processing the material being oxidized, such as a polymer film or other organic residue, in an atmosphere of oxygen at high temperatures of 300° C.-450° C. for several minutes in a complex tool such as a downstream microwave plasma asher. This process typically volatilizes the polymer or organic material being combusted, and hot, gaseous and solid particles of the polymer, or reaction products, are re-deposited onto the substrate, such as a silicon wafer. The ashing process also leaves behind a residual ‘ash’ layer of hydrocarbon material that is undesirable and requires that the silicon wafer be processed through additional steps before the cleaning process is complete.

This re-deposition of particles that stick to the silicon wafer, and the residual ash layer left behind from this process, has been a problem for many years. In order to remove the re-deposited particles, the silicon wafer is processed through a large footprint tool called a wet bench, containing many individual chemical tanks with heaters, timers, and other controls to maintain a uniform process result. The two primary cleaning steps used are Standard Clean 1 (called SC-1) and Standard Clean 2 (called SC-2), collectively called the RCA clean process, in use throughout the IC industry for several decades.

SC-1 is an alkaline solution of ammonium hydroxide, hydrogen peroxide, and deionized water, used mainly to remove organic films or residues and particles. The SC-2 bath is composed of hydrochloric acid, hydrogen peroxide, and deionized water, used to remove metallics from the wafer surface. In addition to these primary cleaning baths, several additional steps are required, including multiple deionized water rinses and alcohol drying. In some cases, an added bake step is used to drive out moisture.

One of the most serious problems of the related art in oxidation-based cleaning is the damage done to the substrate. Thin films of oxide and other semiconductor films are very easily roughened and damaged by the chemicals used in cleaning, and by the non-uniform energy fields used in ashers. As device geometries get smaller, and films are necessarily thinner, the surface damage from these processes reduces yields to an unacceptable level.

Secondly, we will now consider the case of oxidation processes for growing or adding films to a substrate. Oxidation processes for film forming are widely used and comprise a large percent of the total steps used to fabricate an integrated circuit. The most common oxidation process in IC manufacturing, aside from additive-type cleaning reactions, is silicon dioxide growth, an additive-type process. As with cleaning-based oxidation processes, silicon dioxide film growth requires multiple process steps, multiple complex expensive tools or pieces of equipment, gases and chemicals that are not environmentally benign, and high thermal environments that change dopant profiles and can thermally warp the wafer.

Oxidation processes for film forming are performed by several methods, but by far the most common method is thermal oxidation. Thermal oxidation of films typically occurs at elevated temperatures in an oxidizing environment, and the equipment used is generally large and complex. Other methods for growing oxides, such as silicon dioxide and copper oxide, are wet anodization and plasma anodization, but due to several inherent problems, neither of these methods is widely used.

Oxides of silicon are typically grown in a temperature range of 400° C.-1200° C., whether by wet or dry oxidation. Growth times vary from as little as 30 minutes to several hours. Controlled growth of very thin films may take several hours. The growth rate of silicon dioxide is typically increased by growing it under high pressure, in some cases up to 25 atmospheres. Growing oxides at high pressure relaxes the need for high temperatures somewhat, but generally only 100° C.-200° C. Difficulties with both the high-pressure equipment and the process itself have limited the acceptance of this method. Some oxidation processes are conducted at very low pressures, such as below 1 Torr. The cost and complexity of deep vacuum equipment is a problem for manufacturers constantly working to control the overall cost of manufacturing.

In addition to thermal oxidation, RF and DC electron plasma-based oxidation is also used, but the high-energy field of these plasmas causes particle contamination, and the electrical properties are not as good as with thermally grown oxides. Mercury vapor and iodine lamps have also been used as ‘energy drivers’ for silicon oxidation, but were limited to low growth rates.

New integrated circuit designs require gates that are thinner, requiring an oxide thickness of 3 nm or less. It is difficult to control a process for producing a film this thin when the substrate temperature is in the range of 800° C.-900° C., as it is for much of the related art. Even more recent methods to address this problem are not satisfactory, such as using temperatures of 500° C., which still causes distortion of the wafer surface. Some related art processes use a mixture of oxygen and hydrogen to prepare moisture for oxidation, along with a catalyst. This process is both complex and may be difficult to control. Other related art processes use a lamp heating furnace, but in many cases the lamp output is not sufficiently uniform or stable to reliably produce a 3 nm thick film with good control.

Reduction reactions are also widely used, but not to the wide extent of oxidation reactions. Reduction reactions are used, for example, to remove native oxides before epitaxial film growth or other process steps where the presence of a native oxide in not required or is undesirable.

Reduction reactions may also be used to reduce organic films or residues. For example, ammonia and hydrogen are used as reducing agents for the removal of organic layers and residues, especially on surfaces that are oxygen sensitive, such as certain “low-k” films used on advanced integrated circuit devices.

### SUMMARY OF INVENTION

To provide context for describing certain aspects of the invention, six characteristics of existing methods for performing oxidation and/or reduction processes as appreciated by the inventors are discussed below. However, it should be understood that the characterizations below are not intended to narrow the scope of aspects of the invention or claims. To the contrary, certain aspects of the invention may share one or more of the described characteristics with these prior processes. Thus, the discussion below regarding existing processes is intended to aid in describing some of the features of some aspects of the invention, but not to apply to all aspects of the invention.

Firstly, as discussed above, high pressure oxidation of silicon used in IC manufacturing typically requires large footprint, complex equipment, thus requiring significant facility floor space. Further, the size and complexity of this equipment generates particles which become embedded in the oxide film being grown. In the oxidation of polymers, where oxygen is used to remove organic films and residues from the surfaces of silicon wafers, the same problem of large footprint tools taking up expensive factory floor space exists. The use of large ashing tools at high temperatures to oxidize resists creates hot particles of polymer that re-deposit onto the silicon surface, and can only be removed with corrosive wet acids and highly corrosive proprietary organic stripping solutions which are highly polluting. Costly waste treatment is needed.

Secondly, oxidation and reduction reactions in IC manufacturing typically require the use of a considerable volume of toxic chemicals and gases that require expensive abatement processes. Halogen gases such as chlorine and fluorine are used along with many acids and large volumes of water in both oxidative removal of resist films and oxide growth processes. The cost and availability of water alone is a major problem. The cleaning of process chambers requires large volumes of, for example, nitrogen trifluoride, a highly expensive and toxic gas. In short, related art processes are not environmentally friendly, and are energy intensive.

Thirdly, in the oxidation of silicon and other semiconductor and metal films, high temperatures in the range of 700° C.-1200° C. are used. The use of oxidation reactions to remove organic films is also associated with similar high temperatures. These high temperatures can cause migration of dopants introduced near the surface of the substrate, resulting in unwanted changes in the electrical properties of the device. In the high temperature oxidative removal of polymer films, high temperatures in large ashing tools also generate hot sticky particles of resist that redeposit on the wafer and require harsh chemicals to remove.

Fourthly, existing processes require multiple steps. For example, the oxidation of films, for either growth or removal, requires multiple process steps and multiple tools. This makes these processes handling intensive, limiting productivity and decreasing yields. Defects are added to the substrates due to multiple process steps, going in and out of several tools before the process is complete. The multiple steps also reduces throughput and productivity.

A fifth problem of the related art is that they are non-selective, or occur over the entire surface. For example, most oxidation and reduction reactions occur simultaneously over the surface of the substrate in a chamber. In order to selectively oxidize portions of a surface, as is needed in semiconductor device manufacturing, several added steps are needed. These steps involve photoresist imaging and etching processes to end up with isolated islands of oxide, for example. Imaging and etching requires resist coating, baking, photolithography masking, developing, post-baking the resist image, etching away the unwanted oxide, and finally removing the resist image. It would be highly desirable to only deposit oxide only on those selected areas where it is desired, and eliminate the additional patterning and etch steps.

A sixth problem of the prior art processes for oxidizing and reducing reactions is high cost of ownership. For example, they require corrosive and toxic chemicals and gases that cause safety and cost problems, and further are expensive to waste treat. In cleaning reactions, where oxidizing resist chemical strippers are used widely, hot sulfuric acid and large volumes of highly purified water are needed to properly clean wafer surfaces. The cost of manufacturing high purity acids and deionized water, using them in large wet benches, and then waste treating large volumes of chemicals daily adds major cost to semiconductor manufacturing. The total cost of ownership for the combined set of tools and toxic chemicals, gases and liquids, for oxidation and reduction reactions in IC manufacturing is very high. Cost reduction is a major problem needing to be solved in a critical industry.

In one aspect of the invention, a single system is provided that is capable of performing oxidation and reduction-based reactions on a device, thereby alleviating the need for multiple-tools or processes that require significant handling, process time, high energy use, high capital cost, and excessive factory floor space needs. In one illustrative embodiment, a small, robust, simple tool is provided that can perform both oxidation reactions and reduction reactions as used in IC manufacturing. Such reactions may be performed, either alone or in sequence, on a device in the same chamber or other process space, thus avoiding the need to remove the device from the tool when performing both oxidation and reduction processes on the device.

In another aspect of the invention, a method and apparatus for oxidation and reduction reactions are provided that is environmentally friendly. In one embodiment, oxidation and/or reduction processes may be performed without corrosive and toxic gases or chemicals or requiring extensive waste treatment. ‘Green’ processing is becoming a legislated requirement in many factories.

In another aspect of the invention, a method and apparatus are provided to perform oxidation and reduction reactions employing low temperatures, e.g., temperatures at or near room temperature. This aspect of the invention may provide for reduced effects on dopant implant depths or other dopant migration, reduced wafer or other device warpage due to heating, and other benefits.

In another aspect of the invention, a method and system are provided for directed oxidation and reduction reactions on a device, eliminating the related art needed for extra patterning steps to isolate certain areas of oxidation. That is, prior oxidation and/or reduction reactions are non-selective, or occur over the entire surface of the device. For example, to selectively oxidize portions of a surface, as is needed in semiconductor device manufacturing, several added steps are needed. These steps involve photoresist imaging and etching processes to end up with isolated islands of oxide, for example. Imaging and etching requires resist coating, baking, photolithography masking, developing, post-baking the resist image, etching away the unwanted oxide, and finally removing the resist image. Aspects of the invention provide for performing oxidation and/or reduction reactions in selected areas of a device.

In one illustrative embodiment, aspects of the invention provide for both oxidation and reduction reactions that are performed on two primary types of surfaces, organic surfaces and inorganic surfaces. Thus, a total of four different reaction processes may be performed using the same apparatus and with the same general method.

In one illustrative embodiment, the invention provides a novel method and apparatus for processing semiconductor substrates with laser light and reactive gases that provides a single, small system to perform a number of controlled oxidation and reduction reactions using environmentally friendly gases at low temperatures with a low cost of ownership. The reactions are uniform in nature and do not damage the underlying substrate in the process. In this embodiment, uniform oxidation and reduction reactions may be performed on metals and dielectric thin films used in the production of semiconductor devices, thin film heads, optical devices, and/or flat panel displays.

These and other aspects of the invention will become apparent from the detailed description given hereinafter to be read in conjunction with the accompanying drawings. However, it should be understood that the detailed description and specific examples, while indicating illustrative embodiments of the invention, are given by way of illustration only, since various changes and modifications within the spirit and scope of the invention will become apparent to those skilled in the art from this detailed description. Aspects of the invention may be practiced with a variety of lasers and laser wavelengths, scan heads, beam shapes, process gases, substrate materials and processes, and enclosure configurations.

### BRIEF DESCRIPTION OF THE DRAWINGS

The foregoing and other objects, features, and advantages of the invention will become apparent from the more particular description, as illustrated in the accompanying drawings in which like reference characters refer to the same parts throughout the different views. The drawings are not necessarily to scale, emphasis instead being placed upon illustrating aspects of the invention.

FIG. 1 is a schematic diagram illustrating a method of using an oxidation process of the present invention to grow (additive) a blanket layer of oxide film onto a substrate.

FIG. 2 is a schematic diagram illustrating a method of using an oxidation process of the present invention to grow (type) selective portions of an oxide film onto a substrate.

FIG. 3 is a schematic diagram illustrating a method of using an oxidation or reduction process of the present invention to remove a patterned film from a substrate.

FIG. 4 is a schematic diagram illustrating a method of using an oxidation or reduction process of the present invention to remove (subtractive) selective portions of an unpatterned or continuous film from a substrate.

FIG. 5 is a schematic diagram illustrating a method of using an oxidation or a reduction process of the present invention to remove an organic film or an inorganic oxide respectively from a substrate.

FIG. 6 is a schematic diagram illustrating a method of using a reduction process of the present invention to remove (subtractive) selective portions of oxide from a substrate.

FIG. 7 is a schematic diagram illustrating a method of using either an oxidation or reduction process of the present invention to remove (subtractive) selective portions of a film with a hardened crust on top from a substrate.

FIG. 8 is a diagram of the combination of possible oxidation and reduction reactions with pulsed laser radiation and gas types, and the categories of organic and inorganic surfaces or films on which the reactions occur.

FIG. 9 is a block diagram illustrating related art wet processing steps for resist removal compared to a single process step in one embodiment of the invention.

FIG. 10 is a diagram comparing the temperature and footprint of the related art system for oxidation of semiconductor surfaces compared to the temperature and footprint of the present invention.

FIG. 11 is a schematic diagram of an apparatus in an illustrative embodiment of the invention.

### DETAILED DESCRIPTION OF THE PREFERRED EMBODIMENTS

In the following description of the preferred embodiments of the invention, a method and apparatus for performing oxidation and reduction reactions on semiconductor surfaces will be detailed. However, it should be understood that aspects of the invention may be used with any suitable device, such as thin film heads, optical devices, display panels, etc. Thus, aspects of the invention are not limited to use with semiconductor devices.

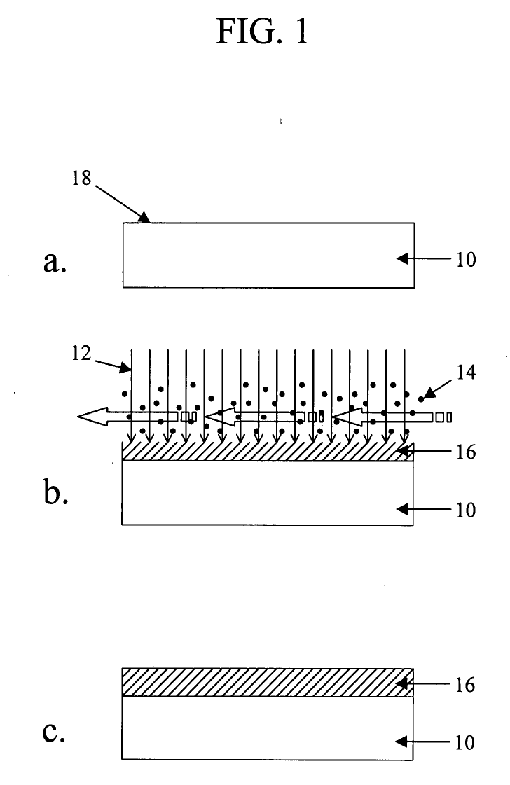

FIGS. 1 to 7 are cross-sectional views of different types of oxidation and reduction reactions on a wafer substrate during the fabrication of a semiconductor device such as a logic or memory integrated circuit chip.

In FIG. 1, one of several possible oxidation reactions that may be performed in accordance with aspects of the invention is shown in a cross-sectional diagram. In this figure, the substrate 10, which may be a semiconductor material such as silicon or a conductive metal film or layer such as copper; 12 represents the laser radiation being scanned across the entire surface of the substrate; 14 represents an oxidizing gas flowing across the surface of the substrate; and 16 represents a film of oxide growing on the substrate as a result of the presence of the oxidizing gas and the laser radiation. In FIG. 1a, the original substrate is shown; in FIG. 1b, the actual process is depicted partway through the oxidation step; FIG. 1c shows the finished substrate 10 with a thin layer of oxide 16 on top. The oxide film grown according to this embodiment of the invention can serve different purposes throughout the manufacturing process and in the finished device. Oxide films, such as silicon dioxide grown on silicon or copper oxide grown of copper, may be used as insulating layers in the device, to isolate portions of the device electrically. Oxide films are also used to protect portions of the device during processing from various kinds of contamination, such as airborne particulates, molecular contamination and physical damage.

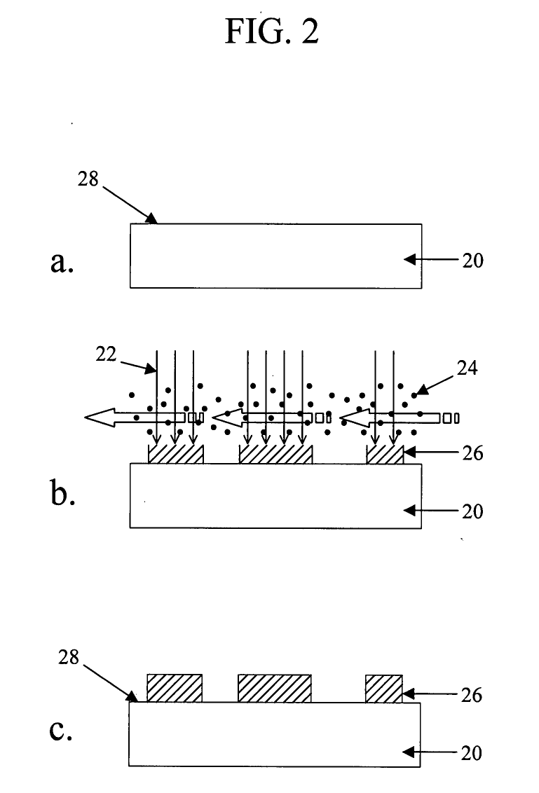

FIG. 2 is a cross-sectional diagram of a portion of a substrate such as a silicon wafer illustrating the same kind of oxidation reaction as shown in FIG. 1, except the laser beam 22 is controlled to address (or illuminate) only selective sites 26 and not address other portions of the substrate surface 28. The flow of oxidizing gas 24 occurs in the same way as shown in FIG. 1, but no oxide is grown in the areas not exposed to the laser radiation, since this is the primary energy driver for the oxidizing reaction. In FIG. 2a, the beginning substrate is shown, being a silicon wafer which can present a silicon surface, or may be a silicon wafer where the surface is coated with a thin layer of copper or other metal or semiconductor film or opto-electronic or optical device that will be oxidized in the actual process step shown in FIG. 2b. In FIG. 2c, the finished cross-section is shown, with the oxide film grown onto the surface of the substrate, ready for the next process step. Another use for oxide films, aside from those cited above, is to provide a good surface for photoresist adhesion or bonding of resist to the oxide. Typical semiconductor manufacturing techniques include many photoresist-imaging steps in the fabrication process to make an integrated circuit. For example, there may be as many as 32 individual separate photoresist masking steps in an advanced IC process. In each step, before the photoresist is coated onto the wafer, an oxide film may be needed since the photoresist may not adequately stick or adhere to the plain silicon surface. It is general practice to apply photoresist onto oxide films for this reason, as it insures good imaging integrity throughout the photolithography processes. In short, layers added to a device in accordance with aspects of the invention may be used for any suitable purpose.

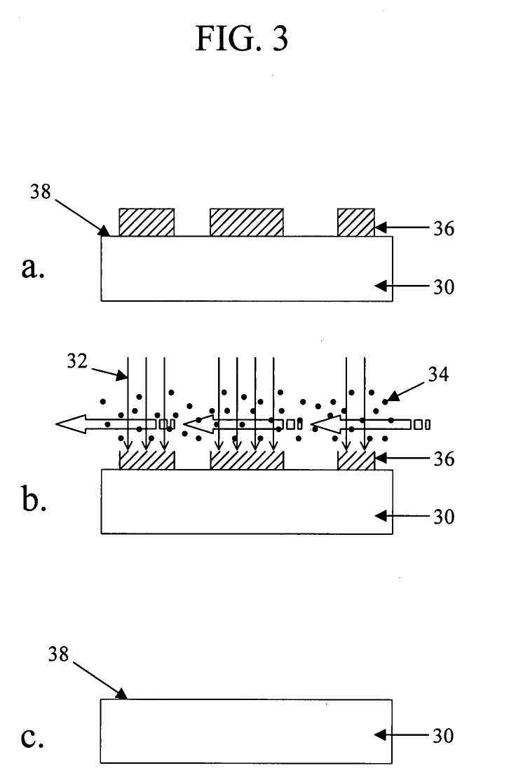

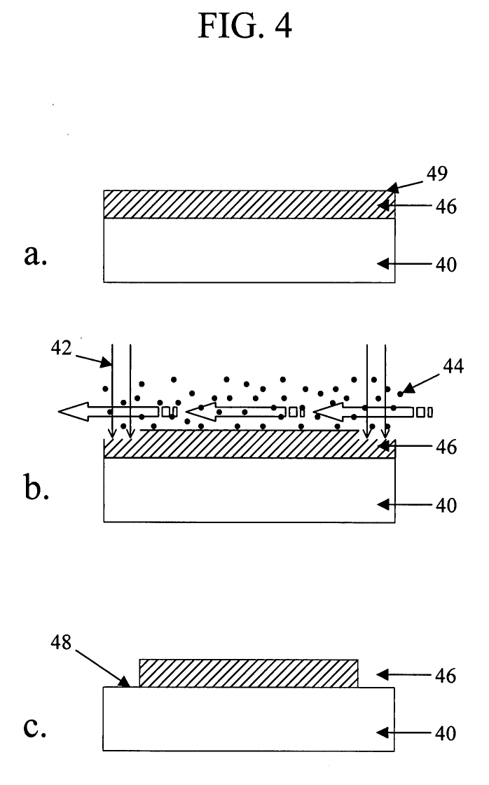

The feature of being able to selectively grow portions of oxide on a substrate is significant, as it can eliminate as many as six individual process steps of the related art in which oxide is currently grown as a film over the entire surface, followed by photoresist coating, baking, exposure and development steps, or other process steps. This forms an image on the substrate to mask the next step, which may include etching. During etching, portions of the unwanted oxide are removed, leaving islands of oxide on the device. The photoresist is then stripped. These six steps can be eliminated by using an embodiment of the present invention wherein selective islands are simply grown on the wafer as shown in FIGS. 2a-2c. FIGS. 1 and 2 illustrate ‘additive’ processes, where a film is added to a substrate by oxidative film growth. The following FIGS. 3 and 4 are ‘subtractive’ processes where either an entire film or portions of a film, are removed.

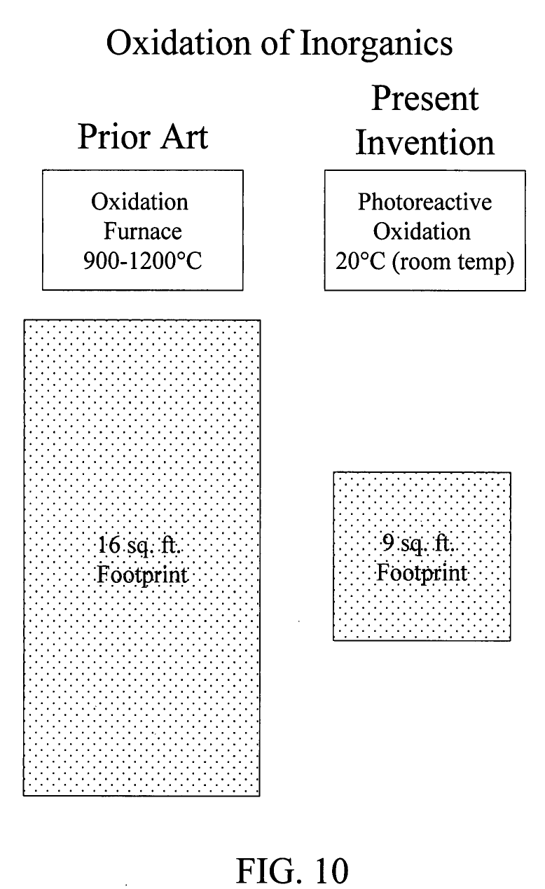

Referring to FIG. 3, patterned photoresist 36 on top of a silicon wafer 30 is shown in FIG. 3a; in FIG. 3b, a flowing gas 34 combines with laser radiation 32 to produce either an oxidizing or reduction reaction, depending on the gas used, to remove the photoresist layer. In accordance with one aspect of the invention, the same apparatus is used, shown in FIG. 10, for both oxidation and reduction reactions. This example can involve the removal of patterned photoresist from the wafer 30 following ion implantation.

In FIG. 3, if oxygen or ozone is used as the gas 34, an oxidizing reaction occurs in which oxygen atoms are added to the photoresist image 36 material on the surface, and the dry combustion reaction that follows will result in complete removal of the photoresist image 36 from surface 38 without causing any damage to the surface. In one illustrative embodiment, a mixture of 85% (by wt.) oxygen and 15% (by wt.) ozone gases are used for gas source 34, and a third harmonic YAG laser at 355 nm is used as radiation source 32.

In FIG. 3, if the gas used is a reducing gas, such as ammonia or hydrogen, patterned photoresist images 36 will be completely removed using the same laser radiation 32 as used for the oxidizing reaction. In one illustrative embodiment of the invention, ammonia gas is used at 100% concentration as the flowing gas 34, and a third harmonic YAG laser operating at 355 nm wavelength is used as the radiation source 32. In another embodiment, hydrogen gas is used in place of the ammonia gas as the reducing agent to completely remove the resist with leaving a residue and without damaging the substrate surface 38. A thin protective oxide may be left after this process, and this oxide will protect the cleaned surface from added contamination, such as molecular contamination.

Reducing reactions are useful to remove photoresist when the substrate surface is sensitive to oxygen, as is the case with some of the “low-k” oxide films required for next generation, high-speed integrated circuits. These low K films are porous, delicate films that are very difficult to clean with prior art methods. For example, wet cleaning causes water absorption that is difficult to remove. A dry process, such as in certain aspects of the present invention, eliminates this problem.

Whether oxidizing or reducing reactions are used to remove photoresist layers or other organic materials, some aspects of the invention may eliminate the major problem associated with conventional wet methods of photoresist removal which involve a complex oxygen ashing tool, followed by a wet bench process which requires large volumes of water and significant volumes of corrosive acids, bases, and solvents, all of which pose costly and complex waste treatment processes. In another embodiment, the patterned images 36 on substrate 30 are composed of oxide or other inorganic material. In this embodiment, a reducing gas such as hydrogen or ammonia may be the gas used shown as 34 in FIG. 3b. In FIG. 3c, the patterned oxide 36 is completely removed by a reduction reaction, leaving surface 38 undamaged and free of oxide. In one embodiment, the reducing gas is 8% hydrogen in an inert gas. In another embodiment, the reducing gas is 100% ammonia. These reducing gas mixtures are used for removal of both organic materials, such as photoresist, or inorganic materials, such as oxides of silicon or other inorganic oxides.

In FIG. 4, three steps are shown for a process using either an oxidizing or reducing gas agent 44 to selectively remove portions of a photoresist film or other organic material on the edges 48 of a silicon wafer or other substrate 40. In FIG. 4a, a substrate 40 is shown with a layer of photoresist 46; in FIG. 4b, flowing gas 44 and laser radiation 42 are directed onto selected portions of the photoresist surface 49 to remove only the photoresist on the edges 48 of a round (or square) substrate 40. In FIG. 4b, note that the resist is being removed only in areas where the laser radiation 42 is directed, while the gas 44 flows across the surface in the presence of laser radiation 44. In FIG. 4c, note that the selected portions of photoresist layer 46 are completely removed from substrate 40. This particular process is called ‘edge bead removal’, and in the related art is accomplished using solvents and a special mechanical wiping device, and a complex tool. The edges of the resist coatings, because of the spin coating dynamics, are left with a thick ridge of resist that can crack and leave resist particles on the substrate, causing contamination defects. The use of an edge bead removal process solves this problem. A feature of at least some aspects of the invention is that this process can be performed dry, eliminating the use of solvents, which are considered a hazardous waste material due to fire potential and carcinogenic properties. The solvent-based edge removal processes cause a solvent residue to be left behind, which necessitates the use of additional wet cleaning and drying steps, adding cost and handling defects. Further, some embodiments of the invention can be control the laser beam or other electromagnetic radiation source to change the width of the edge portion being removed.

As in FIG. 3, FIG. 4 process for edge bead photoresist removal can be accomplished, in a preferred embodiment, with either an oxidizing or a reducing gas agent, where the oxidizing gas is 15% ozone in oxygen, and in the case of a reducing gas being used, the gas is 100% ammonia.

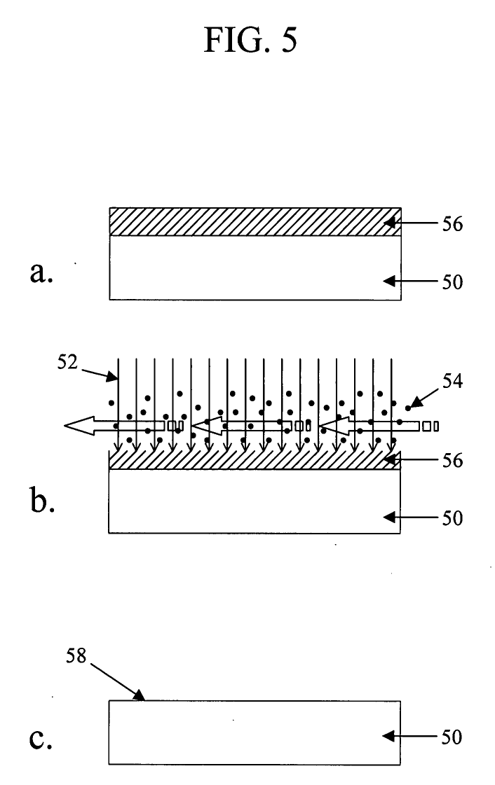

FIG. 5 is a cross section of a portion of a silicon wafer or other substrate 50 used in semiconductor manufacturing. In FIG. 5a, substrate 50 is coated with a blanket film of an organic layer 56 such as a photoresist material. In FIG. 5b, flowing gas 54 is combined with laser radiation 52 and directed onto the surface of the photoresist layer 56, reacting it away by either an oxidation or reduction process, depending on the gas used. In FIG. 5c, the substrate surface has been completely cleaned by the method of the present invention, and there is no damage to the substrate.

As in FIG. 3, which showed the removal of a patterned layer of photoresist, a reducing gas agent such as hydrogen or ammonia can be used, or an oxidizing gas agent such as oxygen or ozone or a combination of oxygen and ozone can be used. In accordance with one embodiment of the invention, the reducing gas agent is 100% ammonia, the laser is a third harmonic YAG laser operating at 355 nm wavelength, the pressure in the reaction chamber is 20 Torr, and the temperature of the substrate is 90° C. This process requires only 3 minutes for a 200 mm substrate, while the related art process, including the wet bench chemical process and dry plasma ashing, requires 9-15 minutes per substrate. In another embodiment, where the layer 56 on substrate 50 in FIG. 5a is a layer of inorganic material, such as silicon dioxide, a reducing gas such as 8% hydrogen or ammonia can be used as the gas 54 in FIG. 5b to completely remove inorganic oxide layer 56 without damaging substrate surface 58.

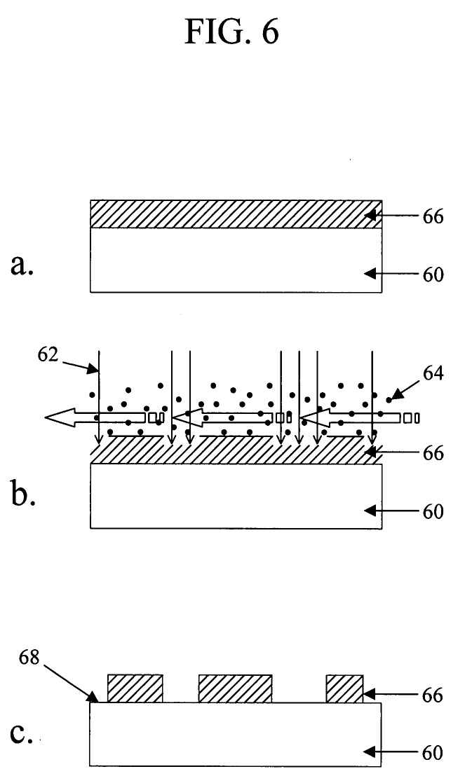

In FIG. 6, a subtractive process is shown in a cross-sectional diagram of a portion of a substrate used in semiconductor manufacturing, such as to make a DRAM (dynamic random access memory) or microprocessor integrated circuit device. In FIG. 6a, substrate 60 is coated with a film of photoresist 66. In FIG. 6b, flowing gas 64 and laser radiation 62 are directed to selective areas of photoresist film 66, and react away those portions where the laser radiation is directed. In FIG. 6c, the result shows that substrate 60 has remaining patterns of photoresist 66, and surface 68 of substrate 60 is not damaged and does not contain any remaining residue from the process. In one embodiment, the gas 64 in FIG. 6b is 15% ozone in oxygen, the laser is a 355 nm YAG, the temperature is 90 centigrade, and the pressure is 15 Torr. This process is a method of direct imaging using the same gas types and method, and the same apparatus used for the processes described in FIG. 1 to FIG. 5 above. In this case, the direct writing eliminates a costly mask and a complex process of the related art in which the photoresist coating 66 is normally exposed with a wafer stepper to form a latent image, a process step called ‘lithography’. This is followed by a wet developing step, where the exposed areas of the photoresist are removed (in a positive working resist), followed by a double de-ionized water rinse step, and an alcohol-drying step. The last step in the related art process is a post-bake. The method in accordance with at least one aspect of the invention permits all of these steps to be accomplished in a single step using the laser radiation 64 and flowing gas 66 shown in FIG. 6, and in FIG. 1 through FIG. 5. In another embodiment, in FIG. 6, layer 66 is an organic oxide, and in FIG. 6b, the gas is a reducing gas such as 8% hydrogen in an inert gas. The oxide is selectively patterned with laser light and gas, eliminating several masking and etching steps as required in the related art.

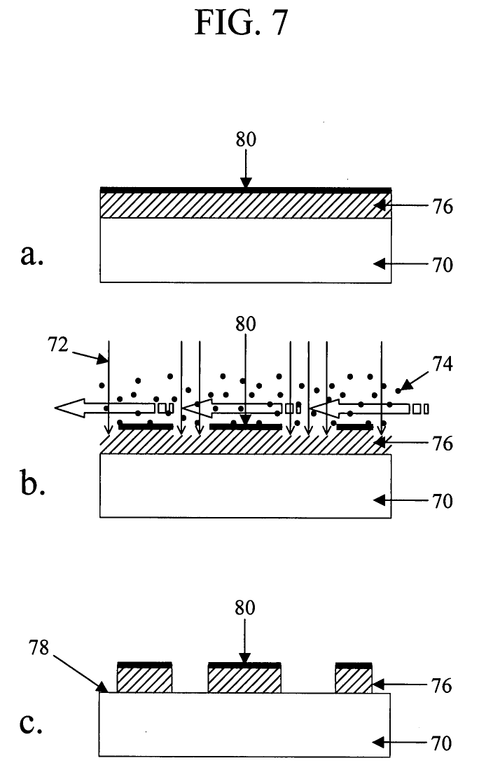

FIG. 7 shows a dry process for removal of an ion implanted resist layer. In FIG. 7a, substrate 70 is coated with a layer of photoresist 76 that has been subjected to an ion implantation process, resulting in a carbonized skin layer 80. In many cases, the resist layer is patterned. The skin layer 80 is created when high energy ions impinge on photoresist layer 76, and greatly densify the molecules of resist, driving out hydrogen, and leaving behind the thin, carbon-like surface layer that is now extremely difficult to remove with conventional, related art methods. In addition, processes such as lift-off can be used with the method of the present invention.

In FIG. 7b, gas molecules 74 flow across the surface of resist layer 76 and carbonized crust layer 80, while simultaneously laser light photons 72 are scanned across the surface. Note that the laser beam photons are directed only in certain areas in the example; in some processes, the laser light may be scanned across the entire surface of the carbonized crust to remove the entire layer 80. Where the laser light 72 and gas flow 74 are applied to carbonized crust layer 80 and resist layer 76, both layers 80 and 76 are fully removed, as shown in the final step in FIG. 7c. In a preferred embodiment, the gas is ammonia, the laser is a 355 nm YAG pulsed diode pumped source, the temperature is 90 centigrade, and the pressure is 15 Torr. There is no damage to substrate 70, which may be a silicon wafer in a preferred embodiment, and also note that all of the resist layer 76 and carbonized layer 80 is fully removed.

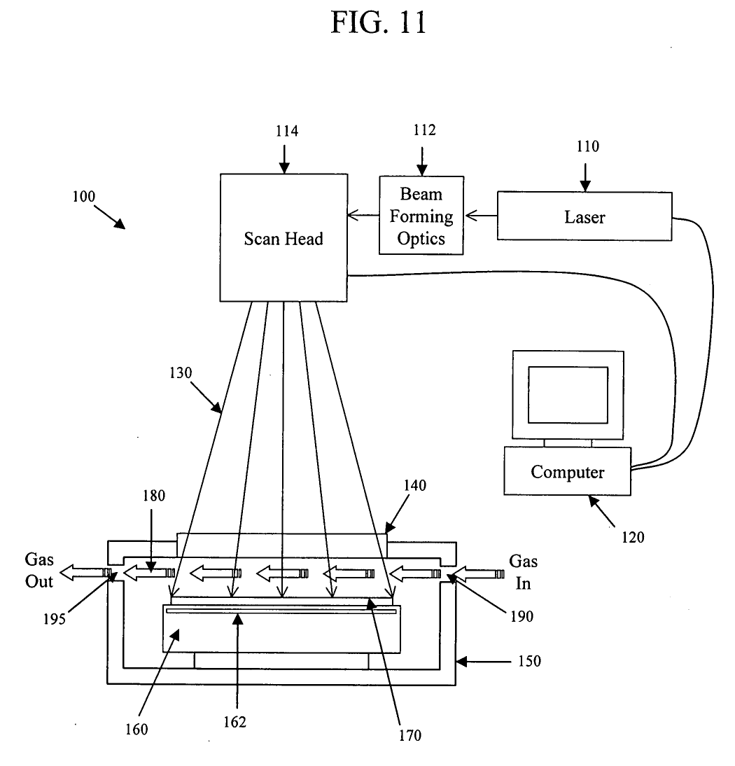

In all of the processes shown in FIGS. 1 through 7, pulsed laser radiation and gas are common elements used in the same apparatus for all of the types of reactions. The apparatus of the present invention can perform all of the varieties of oxidation and reduction reactions in the same small footprint system, using the same laser, scan head, and chamber as shown in FIG. 11.

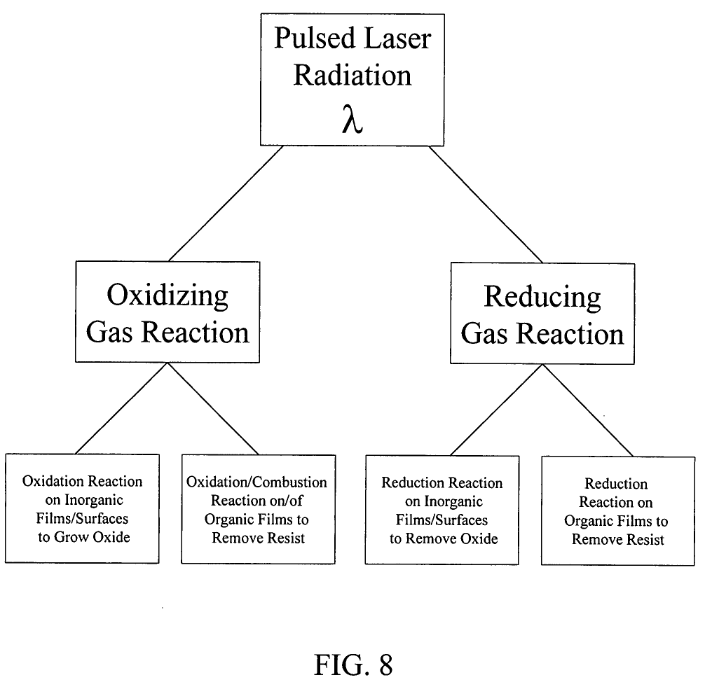

FIG. 8 is a diagram of the types of oxidation and reduction reactions generated with pulsed laser radiation and gas. There are at least four basic combinations that are broken down first into the main category of ‘oxidizing reactions’ and the second category of ‘reduction’ reactions. By one definition, “oxidation is the combination of a substance with oxygen” taken from page 1295 of the American Heritage Dictionary of the English Language, 3^{rd} Edition. Reduction reactions, defined by the same source, page 1515, are “a substance that chemically reduces other substances, especially by donating an electron or electrons”.

In the ‘oxidizing gas reaction’ category, a further sub-division is shown where the oxidation reaction can be on either inorganic surfaces to grow an oxide layer for example, or organic surfaces to remove resist. Both types of reactions may be performed with the oxidizing gas and pulsed laser radiation method and apparatus in some aspects of the invention.

FIG. 8 also shows the category of ‘Reducing Gas Reaction’ further broken down into sub-categories including reduction reactions on inorganic films or surfaces (to remove oxide for example) or on organic films to remove resist. Again, both types of reduction reactions are performed using pulsed laser radiation and gas in accordance with aspects of aspects of the invention.

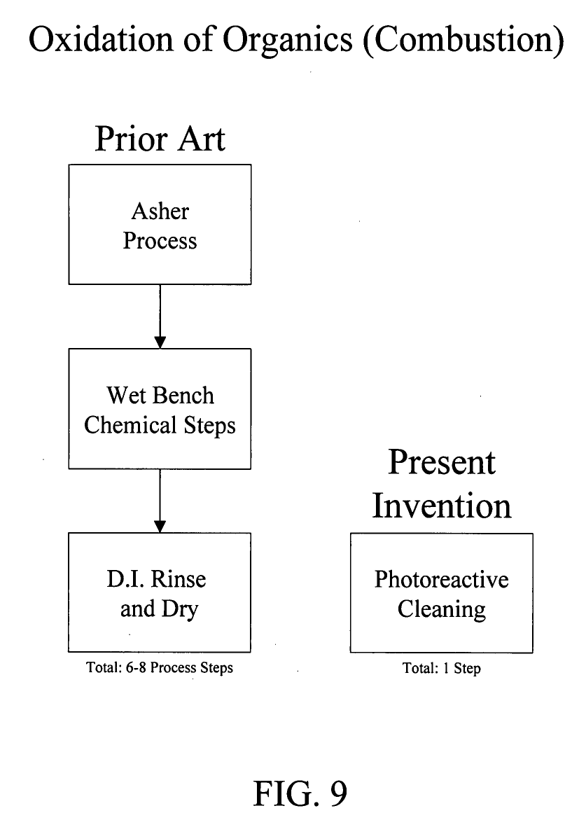

FIG. 9 is a block diagram illustrating related art processing steps of oxidation or oxidative combustion of photoresist films compared to the single step using aspects of the invention. In the prior art process of oxidation of organics, alternatively called ‘photoresist stripping’, ‘organic film removal’, ‘resist removal’ or ‘organic contamination removal’, there are multiple steps used to remove the organic film by oxidation. The first step uses a large and complex tool called an ‘asher’, which basically burns off the organic material in an oxidizing atmosphere, leaving behind an ash layer that must be removed by the second step with a wet bench. In the wet bench, multiple chemical treatments involving strong acids and large volumes of highly purified water are used to take off the remaining residues left from ashing. This method of organic film removal is a standard process that has been in production use worldwide for over 30 years. The chemical cleaning steps are referred to as SC-1 (for Standard Clean 1) and SC-2 (for Standard Clean 2). Hot sulfuric acid, hydrogen peroxide, and hot caustic are used. The third step involves a third piece of equipment for final rinsing and alcohol drying. Significant volumes of water are used, and the water must first be highly purified, then after using, be treated again before disposal. Huge amounts of energy are needed for all the water-related processes, adding considerable cost.

By comparison aspects of the invention allow for the use of only one step, where pulsed laser radiation and gas are introduced into a single chamber, and the oxidation reaction occurs in a single step. In some cases, a first gas used is pumped out and a second gas is flowed into the chamber, but the substrate stays in one place, and the process even with two gases is still a single handling (with a robotic handler) step. The greatly reduced handling using aspects of the invention reduces defects that occur when multiple pieces of equipment are needed to perform an operation.

FIG. 10 shows a diagram comparing the footprint of the related art system for oxidation of semiconductor surfaces compared to the footprint of one embodiment in accordance with the invention. The prior art process for oxidation of inorganics typically involves the use of an oxidation furnace at 900° C.-1200° C., in a system with a typical footprint of 16 square feet. Aspects of the invention can be performed at room temperature or 20° C., in a tool with a footprint as small as 9 square feet. The high cost of factory space in semiconductor facilities makes it important to keep the footprint of tools as small as possible, as each square foot is very expensive.

FIG. 11 illustrates an exemplary implementation of a system 100 that can be used to oxidize surfaces to form oxides of silicon, copper or other films or layers, or to oxidatively combust polymers for cleaning without the use of toxic chemicals and large volumes of purified water. System 100 may also be used to oxidize metals such as copper and aluminum, or form by oxidation layers such as oxy-nitrides, also widely used in for manufacturing of integrated circuits. In one embodiment of the invention, both additive oxidation processes and subtractive oxidation processes can be performed by the same small footprint, low temperature system using non-toxic gases. Related art processes generally require separate tools for oxidation of wafer surfaces, usually involving high temperatures and pressures, and separate tools are used to oxidative combustion or subtractive removal processes of resist and other organic residues or contaminants.

System 100 may also be used to produce reduction reactions on surfaces to, for example, remove native oxides prior to epitaxial deposition in integrated circuit fabrication. Another example of a reduction reaction is the use of ammonia gas to remove organic films and organic contamination, such as patterned resist after etching or ion implantation. This reduction reaction allows for removal of difficult to strip resists without using chemicals, and can be performed on new low-k surfaces which are very sensitive to oxygen and cannot be subjected to conventional related art ashers which use oxygen. In one embodiment, oxidation reactions, including subtractive and additive-type processes, as well as reduction reactions are performed in the same apparatus, eliminating the need to use multiple expensive and complex tools for each of these categories of processes. For example, additive oxidation processes involve specialized furnaces, while subtractive oxidative removal or combustion of organics uses a completely different ashing tool. Aspects of the invention may save considerable cost by combining all of these currently separate processes into a single tool, but also greatly reduces the required factory floor space, which in semiconductor processing is extremely expensive. Furthermore, aspects of the invention may eliminate added handling steps, which has the potential to improve process yields.

System 100 may contain a laser 110, beam forming optics 112, and a scan head 114, used to deliver laser beam 130 into process chamber 150 through a quartz window 140. Inside process chamber 150, gas inlet 190 allows oxidizing or reducing gases to enter and flow in a laminar direction 180 (or other suitable way) across the surface of substrates 170 in the presence of beam radiation 130. The substrates may sit on a vacuum chuck 160 which may contain a heating or cooling element 162. The process gas is exhausted through gas exit port 195. Computer system 120 contains the programs and software to control the various functions of gas flow, laser and scan head parameters, chuck heater and overall system control. The optical subsystem portion of system 100 includes laser 110, beam 130, beam forming optics 112, scan head 114, and window 140.

The laser can be pulsed using repetition rates of from 1000 pulses per second (1 Hz) up to 100,000 Hz. A continuous beam of laser radiation may also be used. Laser wavelengths vary from deep ultraviolet to long wavelength infrared, each giving potentially different results in the oxidizing or reducing reactions.

The implementation illustrated in FIG. 11 is exemplary and other implementations may include more components, fewer components, and/or components in arrangements other that the arrangement of FIG. 11.

Laser 110 may include a device that produces electromagnetic radiation. In one implementation, laser 110 may be a pulsed solid state YAG laser that outputs a wavelength on the order of 355 nm. In another implementation, laser 110 may include a solid-state laser that can output a wavelength in the range from 150 nm to 580 nm. In still another implementation, laser 110 may be a non-solid-state laser and may output other suitable wavelengths.

Beam forming optics module 112 may include an optical device that expands and/or flattens an incoming beam. For example, beam forming optics module 112 may include optical components that receive a circular beam having a first intensity in a middle portion and a second intensity in an edge portion. Beam forming optics module 112 may increase a diameter of the beam and may flatten the first intensity with respect to the second intensity, whereby the difference between the first intensity and the second intensity is smaller at an output of beam forming optics module 112 than at an input of beam forming optics module 112. Implementations may employ beam expansion/flattening modules 112 adapted to expand/flatten beam 130 in a single dimension (e.g., in one plane) and/or in multiple dimensions (e.g. more than one plane).

Scan head 114 may include a device that causes beam 130 to move from a first location on substrate surface 170 to a second location on substrate surface 170. For example, scan head 114 may be controlled via a controller computer 120 that causes scan head 114 to sweep beam 130 across surface 170 according to determined criteria, such as a predetermined scanning pattern. Scanning patterns may include overlapped and/or non-overlapped patterns or may include several scans to create overlap with no overlap in a single scan. Scanning patterns may further include steady state scan patterns, where beam 130 in moved at varying rates across surface 170.

Window 140 may include a device that allows electromagnetic energy to pass through, from the surface outside chamber 150 through window 140 into the chamber so it lands on the surface of substrate 170. In one implementation, window 140 may be made of quartz. Implementations of window 140 may have one or more surfaces coated with an anti-reflection coating. Implementations of window 140 may be adapted to operate with chamber 150 to form a local environment around substrate 170. For example, window 140 and chamber 150 may form a reaction chamber that can be pressurized (i.e., a pressure that exceeds atmospheric pressure) and/or can have a vacuum applied thereto (i.e., a pressure below atmospheric pressure).

Gas inlet 190 may include a device to deliver one or more gases to chamber 150. In one implementation, gas inlet 190 may include a nozzle, a duct, a valve, etc. Gas inlet 190 may be adapted to allow a constant, even steady state flow to reach substrate 170. Chamber 150 may include a device that maintains an environment around substrate 170 while it is being treated with light and gas. Chamber 150 may be made of metal (e.g., aluminum, steel, titanium, etc.) plastic, composite, and/or materials therefrom. For example, an aluminum chamber 150 may allow for removal of ionic charges in the gas stream before gas stream contacts substrate 170. Removal of ionic charges may prevent electrical charging damage to devices on substrate 170, which may be a silicon wafer in one embodiment.

Wafer chuck 160 may include a device to maintain substrate 170 in a determined position with respect to other components in the system. For example, wafer chuck 160 may hold substrate 170 in a position with respect to scan head 114, window 140, or other parts of the system. Implementations of wafer chuck 160 may be heated or cooled and/or fixed in place or movable.

### Experiment #1: Copper Oxidation

The purpose of the first experiment was to determine whether a 355 nm diode pumped, solid-state laser and an ozone/oxygen gas mixture could oxidize a copper substrate. The chamber pressure used was 30 Torr, with a gas flow of 2 slm and gas composition of 18.5% (by wt.) ozone in oxygen. The vacuum chuck temperature used was 90° C. The pulsed laser beam had a diameter of 417 μm and had been optically transformed into a top-hat beam. The wafer was scanned with a series of 16-interleaved scans, each with a pulse spacing of 400 μm for a final pulse spacing of 100 μm, which equates to a 76.5% overlap.

The equation to calculate the speed of the beam, which is determined mainly from the laser repetition rate and the spacing between consecutive pulses is as follows: Laser Scan Speed (in mm/s)=Laser Repetition Rate (in kHz)*Single-Scan Pulse Spacing (in μm).

The laser metrology resulting from this experiment, showing the relevant power readings, and dose and fluence statistics for each scanned area, along with the scanning parameters for each area, are shown in Table 1.

Each set of 16-scans is designated as a pass. The areas with multiple passes had the set of 16-scans run several times. Increasing the number of passes increases the does and does not affect the fluence.

TABLE 1
Parameters for Each Area Scanned with a Top-Hat Beam
with a Final Pulse Spacing of 100 μm

| | Rep Rate | | Avg Power | Pulse Energy | Fluence Range | Dose Range |
|---|---|---|---|---|---|---|
| Site | (kHz) | Passes | (W) | (mJ) | (mJ/cm²) | (mJ/cm²) |
| 1.) | 10 | 1 | 11.35 | 1.135 | 903-1,122 | 12,348-13,799 |
| 2.) | 15 | 1 | 11.51 | 0.767 | 610-759 | 8,348-9,329 |
| 3.) | 20 | 1 | 10.93 | 0.547 | 435-540 | 5,945-6,644 |
| 4.) | 25 | 1 | 10.02 | 0.401 | 319-396 | 4,360-4,873 |
| 5.) | 30 | 1 | 8.83 | 0.294 | 234-291 | 3,202-3,579 |
| 6.) | 30 | 2 | 8.83 | 0.294 | 234-291 | 6,404-7,157 |
| 7.) | 30 | 3 | 8.83 | 0.294 | 234-291 | 9,606-10,736 |

The procedure for this experiment is as follows: a copper-coated wafer was run to determine the oxidation capability of the apparatus and method of the present invention. The wafer was loaded into a magazine on the apparatus shown in FIG. 10, and a robot automatically loaded one wafer at a time into the process chamber. The wafer chuck is already set at its pre-determined temperature, and the gas flow is initiated when the chamber has been pumped down to its base pressure of 2 Torr. When the chamber reaches its programmed pressure the laser beam is the turned on and scans the surface of the wafer according to the parameters cited above. After the laser has finished scanning the substrate, the gas flow is stopped, the chamber is pumped down to its base pressure, and it is purged with nitrogen, and then vented up to atmospheric pressure. The wafer is then automatically unloaded from the chamber with a robot and placed back in its cassette.

The results of this experiment showed that the growth of the oxide is directly related to the dose of laser radiation, not the fluence. Laser fluence over a scanned area is defined as the maximum amount of energy per unit area that a site receives from any single laser pulse. Laser dose over a scanned area is defined at the total amount of energy per unit area that a site receives from all laser pulses that that site is exposed to. This is demonstrated in Table 2.

TABLE 2
Results for Each Scanned Area

| | Fluence | | |
|---|---|---|---|
| | Range | Dose Range | |
| Site | (mJ/cm²) | (mJ/cm²) | Result |
| 1.) | 903–1,122 | 12,348–13,799 | Removed Copper |
| 2.) | 610–759 | 8,348–9,329 | Partial Melting, Partial Oxidation |
| 3.) | 435–540 | 5,945–6,644 | Partial Melting, Partial Oxidation |
| 4.) | 319–396 | 4,360–4,873 | Medium–Low Copper Oxide |
| | | | Growth |
| 5.) | 234–291 | 3,202–3,579 | Low Copper Oxide Growth |
| 6.) | 234–291 | 6,404–7,157 | Medium Copper Oxide Growth |
| 7.) | 234–291 | 9,606–10,736 | High Copper Oxide Growth |

Another result of this experiment was that the entire wafer surface grows a noticeable oxide when exposed to an atmosphere of ozone in oxygen at a chuck temperature of 90° C. even when it is not exposed to laser radiation.

### Experiment #2: Copper Oxidation

The purpose of the second experiment was to determine whether a Gaussian beam profile could produce a more even oxidization of a copper substrate. The chamber pressure used was 30 Torr, with a gas flow of 4 slm and gas composition of 18% (by wt.) ozone in oxygen. The vacuum chuck temperature used was 30° C., which is ambient temperature in the tool. The pulsed laser beam had a Gaussian profile with 1/e² diameters ranging from 688 μm to 1664 μm. The first seven sites on the wafer were scanned with a series of 16-interleaved scans, each with a pulse spacing of 400 μm for a final pulse spacing of 100 μm. The final site was scanned with a series of 64-interleaved scans, each with a pulse spacing of 400 μm, for a final pulse spacing of 50 μm.

The laser metrology resulting from this experiment, showing the relevant power readings, and dose and fluence statistics for each scanned area, along with the scanning parameters for each area, are shown in Table 3.

TABLE 3
Parameters for Each Area Scanned with a Gaussian Beam

| | | 1/e² | Final Pulse | | | | |
|---|---|---|---|---|---|---|---|
| | Rep Rate | Diameter | Spacing | Avg Power | Pulse Energy | Fluence Range | Dose Range |
| Site | (kHz) | (μm) | (μm) | (W) | (mJ) | (mJ/cm²) | (mJ/cm²) |
| 1.) | 10 | 688 | 100 | 11.35 | 1.135 | 689-829 | 12,625-13,476 |
| 2.) | 15 | 688 | 100 | 11.51 | 0.767 | 466-561 | 8,535-9,111 |
| 3.) | 20 | 688 | 100 | 10.93 | 0.547 | 332-399 | 6,079-6,489 |
| 4.) | 25 | 688 | 100 | 10.02 | 0.401 | 243-293 | 4,458-4,759 |
| 5.) | 30 | 688 | 100 | 8.83 | 0.294 | 179-215 | 3,274-3,495 |
| 6.) | 10 | 1664 | 100 | 11.35 | 1.135 | 130-158 | 12,651-13,538 |
| 7.) | 15 | 1587 | 100 | 11.51 | 0.767 | 97-126 | 8,393-9,292 |
| 8.) | 20 | 1587 | 100 | 10.93 | 0.547 | 69-90 | 5,978-6,618 |
| 9.) | 15 | 1587 | 50 | 11.51 | 0.767 | 108-126 | 35,198-35,623 |

The results of this experiment showed that the reaction that grows the copper oxide has a fluence threshold. Once the fluence threshold is exceeded, the oxide growth is directly related to the laser radiation dose. This is demonstrated in Table 4. Note that Site 8 has no oxide growth.

TABLE 4
Results for Each Scanned Area

| | Fluence | | |
|---|---|---|---|
| | Range | Dose Range | |
| Site | (mJ/cm²) | (mJ/cm²) | Result |
| 1.) | 689–829 | 12,625–13,476 | Removed Copper |
| 2.) | 466–561 | 8,535–9,111 | Melted Copper |
| 3.) | 332–399 | 6,079–6,489 | Partial Melting, Partial Oxidation |
| 4.) | 243–293 | 4,458–4,759 | Partial Melting, Partial Oxidation |
| 5.) | 179–215 | 3,274–3,495 | Partial Melting, Partial Oxidation |
| 6.) | 130–158 | 12,651–13,538 | Uneven Copper Oxidation, |
| | | | Thickness Range: Low–High |
| 7.) | 97–126 | 8,393–9,292 | Uneven Copper Oxidation, |
| | | | Thickness Range: None–Low |
| 8.) | 69–90 | 5,978–6,618 | No Reaction |
| 9.) | 108–126 | 35,198–35,623 | Uneven Copper Oxidation, Thickness |
| | | | Range: Medium–High |

This experiment also proved that laser oxidation of copper does not require a heated vacuum chuck. The reaction can occur at ambient temperature.

### Experiment #3: Copper Oxidation

The purpose of the third experiment was to determine whether a rounded beam profile could produce a more even oxidization of a copper substrate. This profile has a rounded top with a steep drop-off at the edges and can be roughly defined by Equation 1 where F(r) is the intensity of the laser beam profile at a distance, r, from the center and where R is the radius of the beam.

$$\text{Equation 1:} \text{Equation Defining a Rounded Beam Profile} \\ F ( r ) = \sqrt{1 - {( \frac{r}{R} )}^{2}} \qquad$$

The chamber pressure used was 100 Torr, with a gas flow of 4 slm and gas composition of 18% (by wt.) ozone in oxygen. The vacuum chuck temperature used was 30° C. The pulsed laser beam had a rounded profile with a diameter of 1400 μm. The wafer was scanned with a series of 16-interleaved scans, each with a pulse spacing of 800 μm for a final pulse spacing of 200 μm, which equates to a 85.7% overlap. Each set of 16-scans is designated as a pass. The areas with multiple passes had the set of 16-scans run several times.

The laser metrology resulting from this experiment, showing the relevant power readings, and dose and fluence statistics for each scanned area, along with the scanning parameters for each area, are shown in Table 5.

TABLE 5
Parameters for Each Area Scanned with a Rounded Beam

| | Rep Rate | | Avg Power | Pulse Energy | Fluence Range | Dose Range |
|---|---|---|---|---|---|---|
| Site | (kHz) | Passes | (W) | (mJ) | (mJ/cm²) | (mJ/cm²) |
| 1.) | 10 | 1 | 11.26 | 1.126 | 162-122 | 3,459-3,037 |
| 2.) | 15 | 1 | 11.445 | 0.763 | 110-83 | 2,344-2,058 |
| 3.) | 15 | 2 | 11.445 | 0.763 | 110-83 | 4,688-4,116 |
| 4.) | 15 | 3 | 11.445 | 0.763 | 110-83 | 7,032-6,175 |

The results of this experiment showed that a rounded beam profile could produce a much more even copper oxide growth than either a Gaussian or a top-hat beam profile. This is demonstrated in Table 4.

TABLE 6
Results for Each Scanned Area

| | Fluence | | |
|---|---|---|---|
| | Range | Dose Range | |
| Site | (mJ/cm²) | (mJ/cm²) | Result |
| 1.) | 162–122 | 3,459–3,037 | Removed Copper |
| 2.) | 110–83 | 2,344–2,058 | Very Even Low Copper Oxide Growth |
| 3.) | 110–83 | 4,688–4,116 | Very Even Medium Copper Oxide |
| | | | Growth |
| 4.) | 110–83 | 7,032–6,175 | Very Even High Copper Oxide Growth |

Experiment #4: Hardbaked Photoresist Removal with O2/O3

The standard application that has been used as a benchmark for determining system performance is the removal of 7,000 Å-10,000 Å of hardbaked Rohm and Haas 1818 photoresist from silicon wafers. The chamber pressure used is 30 Torr, with a gas flow of 4 slm and gas composition of 18% (by wt.) ozone in oxygen. The vacuum chuck temperature used was 90° C. The pulsed laser beam had a top-hat profile with a diameter of 417 μm. The wafer is scanned with a series of 4-interleaved scans, each with a pulse spacing of 400 μm for a final pulse spacing of 200 μm, which equates to a 52.0% overlap. These parameters clean the surface of the wafer without detectable damage to the wafer surface, and without any remaining residues.

Experiment #5: Ion Implanted Photoresist Removal with O2/O3

An experiment was performed as follows: several samples consisting of wafers (hereafter samples) coated with approximately 7,000 Å of Shipley 1818 photoresist were ion implanted at doses of 5×10¹², 5×10¹³, 5×10¹⁴, 5×10¹⁵, and 5×10¹⁶ atoms per square centimeter. A control sample (hereafter control) consisting of 7,000 Å of Shipley 1818 photoresist was also prepared. The samples were all cleaned using the following process: The wafers were each placed in a chamber where the chuck was at a temperature of 100° C. and pumped down to vacuum (approximately 1 Torr). A primary gas consisting of 15% (by wt.) ozone in oxygen was introduced into the chamber at a flow rate of 5 SLM along with a second gas consisting of 100% water vapor at a flow rate of 250 SCCM. The chamber was brought to a pressure of 50 Torr. The wafers were scanned using a 355 nm solid-state laser with an energy density at the surface of the wafer in the range of 400-1,000 mJ/cm² per pulse.

In this experiment, a single step process and a single gas were used to remove the entire photoresist layer, including removal of high dose implants of 5×10¹⁶. The surface of the wafer was cleaned without detectable damage to the wafer surface, and there were no residues remaining. This exemplary implementation did produce shattering and break up of the crust layer, resulting is crust portions being deposited on the sidewalls of the chamber. A portion of the crust further landed on the wafer. These particles (crust portions) are not thermally adhered to the wafer, and processing the wafer in a simple rinser-dryer module, may result in a clean wafer surface.

In prior art processes, crust break-up is accompanied by considerable heating of crust particles, such that they land and stick to the wafer via thermal adhesion, a problem that requires the use of a complex wet bench cleaning process, including strong corrosive acids to break down the thermally reacted crust material.

Experiment #6: Hardbaked Photoresist Removal with H2

In this experiment, hydrogen was compared to an oxygen/ozone gas mixture to determine if it was as effective as a reactive gas to remove 7,000 Å of hardbaked Rohm and Haas 1818 photoresist from silicon wafers, which is the standard application that has been used as a benchmark for determining system performance. The parameters used on the hydrogen wafer were as follows: the chamber pressure used was 400 Torr, with a gas flow of 8 slm, a gas composition of 12% (by vol.) hydrogen in argon and a vacuum chuck temperature of 30° C. The parameters used on the oxygen/ozone wafer were as follows: the chamber pressure used was 130 Torr, with a gas flow of 9 slm, a gas composition of 15% (by wt.) ozone in oxygen and a vacuum chuck temperature of 30° C. The pulsed laser beam had a Gaussian profile. The wafers were scanned with a series of repetition rates from 10-30 kHz, with a scan speed (in mm/s) equal to 175 (the pulse spacing in μm) times the repetition rate (in kHz), and a line spacing of 0.1 mm.

The results of this experiment showed that the reaction of laser radiation and hydrogen gay on photoresist is very similar to that of an oxidizing gas mixture. Both reactions remove the photoresist with a bright blue gas reaction zone (GRZ).

The present invention has been explained specifically with reference to preferred embodiments thereof but it will be apparent that the invention is not restricted to the embodiments described above but may be modified variously within a range not departing from the gist thereof.

1. A method for processing a device, comprising:
providing a processing apparatus including a chamber constructed and arranged to receive a device to be processed, the processing apparatus being arranged to perform an oxidation process or a reduction process on the device with the device in the chamber;
providing the device in the chamber; and
performing at least one of an oxidation process or a reduction process on the device in the chamber by exposing a surface of the device to a gas and to illumination having only a range of wavelengths between about 280 and 532 nm, wherein the illumination causes material at the surface of the device to react with the gas.

2. The method of claim 1, wherein the step of providing a processing apparatus includes:
providing the processing apparatus with a chamber constructed and arranged to receive a semiconductor wafer, and the processing apparatus is arranged to perform both an oxidation process to remove or add a layer to the semiconductor wafer and a reduction process to remove or add a layer to the semiconductor wafer, wherein the oxidation process and the reduction process are performable on the device in the chamber.

3. The method of claim 2, wherein the step of performing includes:
performing an oxidation process to remove or add a layer to the semiconductor wafer; and
removing the semiconductor wafer from the chamber.

4. The method of claim 2, wherein the step of performing includes:
performing a reduction process to remove or add a layer to the semiconductor wafer; and
removing the semiconductor wafer from the chamber.

5. The method of claim 2, wherein the step of performing includes:
performing an oxidation process to remove or add a layer to the semiconductor wafer;
performing a reduction process to remove or add a layer to the semiconductor wafer; and
removing the semiconductor wafer from the chamber.

6. The method of claim 1, wherein the step of performing includes:
performing an oxidation reaction to remove an organic layer from the device.

7. The method of claim 1, wherein the step of performing includes:
performing an oxidation reaction to add an inorganic layer to the device.

8. The method of claim 1, wherein the step of performing includes:
performing a reduction reaction to remove an organic layer from the device.

9. The method of claim 1, wherein the step of performing includes:
performing a reduction reaction to remove an inorganic layer from the device.

10. The method of claim 1, wherein the step of performing includes:
performing a reduction reaction on the device; and
performing an oxidation reaction after the reduction reaction to remove an organic layer from the device.

11. The method of claim 1, wherein the reaction of the gas and the material at the surface of the device is a reduction reaction that causes the material and gas to form a gaseous byproduct and removal of material from the device, and the material is a photoresist.

12. The method of claim 1, wherein the step of performing at least one of an oxidation process or a reduction process includes maintaining a temperature of the device surface at between about 15 to 150 degrees C.

13. The method of claim 1, wherein the illumination is laser light having a wavelength of about 355-532 nm.

14. The method of claim 13, wherein the laser light is pulsed at a rate of between about 5-100 khz.

15. The method of claim 13, wherein the laser light has a pulse energy of about 0.1 mJ-1.5 mJ.

16. The method of claim 1, wherein the step of performing at least one of an oxidation process or a reduction process includes:
providing the gas at a flow rate of about 5-50 slm.

17. The method of claim 1, wherein a pressure in the chamber during the oxidation process or a reduction process is about 5 to 500 Torr.

18. The method of claim 1, wherein the gas is an oxygen gas including about 15% ozone for oxidation reactions, and is an ammonia gas for reduction reactions.

19. The method of claim 1, wherein the illumination is directed at the surface of the device so as to cause oxidation or reduction reactions at selected portions of the device surface.

20. The method of claim 1, wherein the oxidation process or reduction process includes:
providing a gas near a surface of the device at a flow rate of about 5-50 slm;
establishing a pressure in the chamber of about 5 to 500 Torr;
maintaining a temperature of the device surface at between about 15 to 150 degrees C; and
illuminating the gas using laser illumination to cause the gas to react with at least a portion of the device surface, the laser illumination having a wavelength of about 280-532 nm, a pulse rate of about 5-100 kHz, and a pulse energy of about 0.1 mJ-1.5 mJ.

21. The method of claim 20, wherein the gas is an oxygen gas including about 15% ozone for oxidation reactions, and is an ammonia gas for reduction reactions.

22. A method for processing a device, comprising:
providing a processing apparatus including a chamber constructed and arranged to receive a device to be processed and to maintain a pressure in the chamber below one atmosphere;
providing the device in the chamber; and
performing an oxidation process or a reduction process on the device in the chamber by exposing a surface of the device to a gas and to illumination consisting of a range of wavelengths that is substantially transparent to and not absorbed by the gas, wherein the illumination causes material at the surface of the device to react with the gas.

23. The method of claim 22, wherein the range of wavelengths is from about 280 nm to 532 nm.

24. The method of claim 22, wherein the illumination consists of radiation having a wavelength of about 355 to about 532 nm.

25. The method of claim 22, wherein the gas has a concentration of at least about 15% by weight, and the gas is ozone that is mixed with oxygen.

26. The method of claim 22, wherein the gas has a concentration of at least about 8% by weight, and the gas is ammonia or hydrogen.

27. The method of claim 22, wherein a temperature at the surface of the device is maintained below 150 C during the oxidation or reduction process.

28. A method for processing a device, comprising:
providing a processing apparatus including a chamber constructed and arranged to receive a device to be processed and to maintain a pressure in the chamber below one atmosphere;
providing the device in the chamber; and
performing an oxidation process or a reduction process on the device in the chamber by exposing a surface of the device to a gas and to illumination arranged to cause the gas and material at the surface to react, wherein the gas has a concentration of at least 8% by weight.

29. The method of claim 28, wherein the illumination consists of a range of wavelengths from 280 nm to 532 nm.

30. The method of claim 28, wherein the gas has a concentration of at least about 15% by weight, and the gas is ozone that is mixed with oxygen.

31. The method of claim 28, wherein the gas is ozone, ammonia or hydrogen.

32. The method of claim 28, wherein a temperature at the surface of the device is maintained below 150 C during the oxidation or reduction process.

33. The method of claim 28, wherein the reaction of the gas and the material at the surface of the device is an oxidation reaction that causes the material and gas to form a gaseous byproduct and removal of material from the device, and wherein the material is a photoresist.

34. A method for processing a device, comprising:
providing a processing apparatus including a chamber constructed and arranged to receive a device to be processed and to maintain a pressure in the chamber below one atmosphere;
providing the device in the chamber; and
performing an oxidation process or a reduction process on the device in the chamber by exposing a surface of the device to a gas and to illumination that causes material at the surface of the device to react with the gas, wherein the oxidation or reduction process occurs while a temperature at the surface of the device is maintained below 150 C.

35. The method of claim 34, wherein the illumination consists of a range of wavelengths from about 280 nm to 532 nm.

36. The method of claim 34, wherein the illumination consists of radiation having a wavelength of about 355 to about 532 nm.

37. The method of claim 34, wherein the gas has a concentration of at least about 15% by weight, and the gas is ozone that is mixed with oxygen.

38. The method of claim 34, wherein the gas has a concentration of at least about 8% by weight, and the gas is ammonia or hydrogen.

39. A method for processing a device, comprising:
providing a processing apparatus including a chamber constructed and arranged to receive a device to be processed and to maintain a pressure in the chamber below one atmosphere;
providing the device in the chamber; and
performing an oxidation process or a reduction process on the device in the chamber by exposing a surface of the device to a gas and to illumination that causes material at the surface of the device to react with the gas, wherein the illumination is pulsed at a rate of 5-100 kHz.

40. The method of claim 39, wherein the illumination is pulsed at a frequency of 10-30 kHz.

41. The method of claim 39, wherein the illumination consists of a range of wavelengths from about 280 nm to 532 nm.

42. The method of claim 39, wherein the illumination consists of a range of wavelengths from about 355 to about 532 nm.
